(19) United States
(12) Patent Application Publication
(10) Pub. No.: US 2008/0122071 A1
(43) Pub. Date: May 29, 2008

(54) Heat dissipating semiconductor package and fabrication method therefor

(75) Inventors: Wen-Tsung Tseng, Taichung (TW); Ho-Yi Tsai, Taichung Hsien (TW); Chien-Ping Huang, Hsinchu Hsien (TW); Chih-Wei Chang, Taichung (TW); Cheng-Hsu Hsiao, Taichung Hsien (TW)

Correspondence Address: Edwards Angell Palmer & Dodge LLP, P.O. Box 55874, Boston, MA, 02205, US

(73) Assignee: Siliconware Precision Industries Co., Ltd., Taichung (TW)

(21) Appl. No.: 11/986,362

(22) Filed: Nov. 21, 2007

(30) Foreign Application Priority Data
Nov. 24, 2006 (TW) 095143487

(51) Int. Cl. H01L 23/373

(52) U.S. Cl. 257/720; 438/122; 257/E23.11

(57) ABSTRACT

A heat dissipating semiconductor package and the fabrication method therefor are provided. The fabrication method for the heat dissipating semiconductor package mainly includes steps of: containing a substrate having a chip mounted thereon in an aperture of a carrier, wherein the carrier has an electroconductive layer; allowing a heat dissipating structure having supporting portions to be mounted on and electrically connected to the electroconductive layer of the carrier via the supporting portions thereof while heat dissipating structure being mounted on the chip; after an encapsulation process and removing a part of the encapsulant above the heat dissipating sheet by lapping to expose a surface of the heat dissipating structure from the encapsulant, depositing and forming a metal passivation layer on the surface of the heat dissipating structure by electroplating for preventing the heat dissipating structure from oxidizing.

### BACKGROUND OF THE INVENTION

1. Field of the Invention

The present invention generally relates to a semiconductor package and a fabrication method therefor, and more particularly, to a heat dissipating semiconductor package, with which a heat dissipating structure is integrated, and the fabrication method therefor.

2. Description of Related Art

Along with the demand for lighter and smaller electronic product, it is the main stream to produce ball grid array (BGA) semiconductor package with sufficient amounts of input/output connections for the chips with dense electronic components and electronic circuits. However, a lot of heat is generated in the semiconductor package with dense electronic components and electronic circuits. If heat cannot be dissipated immediately from the surface of the chip, the electricity function and product stability of the semiconductor chip will be affected thereby. In addition, the semiconductor chip encapsulated with an encapsulant being made of an encapsulation resin that is poor in thermal conductivity, where the thermal conductivity coefficient of the encapsulation resin is around 0.8 w/m° K, the heat generated from the chip active surface with a plurality of circuits thereon is unable to be effectively and quickly dissipated through the encapsulant, thus the chip functions and durability are affected.

In view of the above heat dissipating problems in the conventional ball grid array semiconductor package, U.S. Pat. Nos. 6,458,626, and 6,444,498 disclosing a BGA semiconductor package having a heat dissipating structure attached thereto is illustrated in FIGS. 1A-1C. The semiconductor package has a substrate 13, a semiconductor chip 10 mounted on the substrate 13, a heat dissipating sheet 11 directly attached on the semiconductor chip 10, an interface layer 15 formed on a surface of a heat dissipating sheet 11, and an encapsulant 14 completely encapsulate the heat dissipating sheet 11 and the semiconductor chip 10, wherein the heat dissipating sheet 11 is extended outwardly to maximize the exposed surface thereof and prevent the resin flush from the occurrence. The interface layer 15 provided has a poor bonding with the encapsulant 14 for exposing the surface of the heat dissipating sheet 11 from the encapsulant 14 after a further cutting process.

As shown in FIG. 1B, if a bonding between the interface layer 15 (e.g., a plated gold layer) and the heat dissipating sheet 11 is stronger than that between the interface layer 15 and the encapsulant 14, the interface layer 15 is kept on the heat dissipating sheet 11 after the encapsulant 14 has been removed after the further cutting process.

Alternatively, as shown in FIG. 1C, if a bonding between the interface layer 15 (e.g., an adhesive tape made up of polymeric resin) and the heat dissipating sheet 11 is weaker than that between the interface layer 15 and the encapsulant 14, the interface layer 15 will be removed from the heat dissipating sheet 11 with the encapsulant 14.

However, as the heat dissipating sheet 11 is extended outwardly, the cutting tool goes directly through the heat dissipating sheet, which is usually made of metal such as copper or aluminum, and easily causes metal burrs of the heat dissipating sheet, thereby affecting an appearance of the package, increasing worn out the cutting knife, and causing higher production cost and lower production efficiency.

In addition, Taiwan Patent No. 1255047 discloses a heat dissipating semiconductor package with the following steps illustrated in FIGS. 2A to 2C. A substrate 23 having a semiconductor chip 20 mounted thereon is positioned into a predetermined aperture 220 of a carrier 22, wherein, a planar size of the substrate 23 is close to a predetermined planar size of the semiconductor package. A heat dissipating structure 21 comprising a heat dissipating sheet 211 and a supporting portion 212 is mounted on a carrier 22 for positioning the semiconductor chip 20 beneath the heat dissipating sheet 211. An encapsulant 24 is formed on the substrate 23 and the carrier 22 to encapsulate the semiconductor chip 20 and the heat dissipating structure 21 by a molding process, wherein, a planar size covered by the encapsulant 24 is greater than that defined by the supporting portion 212 of the heat dissipating structure 21. A cutting process is performed to cut along outlines of a predetermined size of the semiconductor package, and thereby portions going beyond the predetermined planar size of the semiconductor package, such as a portion of the encapsulant 24 and the supporting portion 212 are removed.

However, as the heat dissipating structure 21 of the above-mentioned heat dissipating semiconductor package does not being contacted with the semiconductor chip 20, a lot of thermal resistance is presented therein, and heat dissipation efficiency for the chip is poor.

Furthermore, as shown in FIGS. 3A and 3B, which are diagrams of a heat dissipating semiconductor package according to U.S. Pat. No. 5,886,408, wherein a heat dissipating structure 31 is directly mounted on a semiconductor chip 30; a molding process is performed to form an encapsulant 34 that encapsulates the heat dissipating structure 31 and the semiconductor chip 30; and then a surface of the heat dissipating structure 31 is exposed by lapping a part of the encapsulant 34.

However, due to the heat dissipating structure 31 exposed from the encapsulant 34 after lapping are mainly made of copper in the aforementioned heat dissipating semiconductor packages, the heat dissipating structure 31 are oxidize and form a cupric oxide after being exposed to the air for a long time, thereby affecting not only an appearance of the package but also a heat dissipating efficiency of the heat dissipating sheet.

Therefore, there is an urgent need providing a semiconductor package and fabrication method therefor that can overcome the above-mentioned drawbacks.

### SUMMARY OF THE INVENTION

In view of the disadvantages of the prior art mentioned above, it is a primary objective of the present invention to provide a heat dissipating semiconductor package and a fabrication method therefor, which is capable of preventing a part of heat dissipating structure exposed from an encapsulant from being oxidized, and further preventing an undesirable appearance and a reduced heat dissipating efficiency due to oxidation.

It is another objective of the present invention to provide a heat dissipating semiconductor package and a fabrication method therefor, which is capable of reducing worn out of a cutting tool in the fabrication process.

It is a further objective of the present invention to provide a heat dissipating semiconductor package and a fabrication method therefor for allowing a direct contact of a heat dissipating structure with a semiconductor chip, thus obtaining an excellent heat dissipating efficiency.

To achieve the aforementioned and other objectives, a fabrication method for a heat dissipating semiconductor package is provided according to the present invention. The fabrication method of heat dissipating semiconductor package of the present invention comprises: providing a substrate having a semiconductor chip mounted thereon and a carrier having an electroconductive layer on a surface thereof, wherein, a size of the substrate is close to a predetermined size of the semiconductor package, and the carrier has at least one aperture for containing the substrate therein; providing a heat dissipating structure having a heat dissipating sheet and a plurality of supporting portions extended downwardly from edges of the heat dissipating sheet; mounting the supporting portions of the heat dissipating structure on the carrier with the semiconductor chip being connected under the heat dissipating sheet, and electrically connecting the supporting portions to the electroconductive layer; forming an encapsulant on the substrate and the carrier to encapsulate the semiconductor chip and the heat dissipating structure; removing a part of the encapsulant above the heat dissipating sheet of the heat dissipating structure by lapping for allowing a part of the heat dissipating sheet to be exposed from the encapsulant; depositing a metal passivation layer on the part of the heat dissipating sheet exposed from the encapsulant via the electroconductive layer of the carrier by a electroplating process; cutting according to the predetermined size of the semiconductor package for obtaining the semiconductor package of the present invention.

The heat dissipating sheet of the heat dissipating structure has a protruding portion on a top center area thereof for allowing a top surface of the protruding portion to be exposed from the encapsulant after lapping the part of the encapsulant. The top surface of the protruding portion is deposited with a metal passivation layer, which is made of nickel, chromium, tin, gold, palladium, or the like, by electroplating for prevent it from oxidation, meanwhile, a remaining part of the heat dissipating sheet is still encapsulated inside the encapsulant, for increasing a bonding between the heat dissipating structure and the encapsulant. The heat dissipating sheet further has an extension portion at each of four corners thereof for being connected with the supporting portions, which allows a cutting tool cutting through the extension portions only rather than the entire heat dissipating sheet according to the predetermined size of the semiconductor package in a later cutting process, thereby reducing worn out of the cutting tool. A surface, which is opposing to a surface of the part of the heat dissipating sheet exposed form the encapsulant, of the heat dissipating sheet of the heat dissipating structure is contacted with the semiconductor chip via a heat conductive gel mounted therebetween, thus heat generated during an operating of the semiconductor chip is dissipated via the heat dissipating structure.

The present invention further discloses a heat dissipating semiconductor package that comprises: a substrate; a semiconductor chip mounted on and electrically connected to the substrate; a heat dissipating sheet mounted on the semiconductor chip via a heat conductive gel; an encapsulant formed on the substrate to encapsulate the semiconductor chip with a top surface of the heat dissipating sheet exposed therefrom; and a metal passivation layer formed on the top surface of the heat dissipating sheet exposed from the encapsulant by means of electroplating. The heat dissipating sheet has a protruding portion on a center area thereof, and a top surface of the protruding portion is exposed from the encapsulant and is covered by the metal passivation layer in order to prevent the top surface of the protruding portion from oxidization. The heat dissipating sheet further has an extension portion at each of four corners thereof, where side surfaces of the extension portions are flush with those of the encapsulant.

Furthermore, a fabrication method for a heat dissipating semiconductor package according to another preferred embodiment of the present invention comprises steps of: providing a substrate having a semiconductor chip mount thereon and a carrier having an electroconductive layer on a surface thereof, wherein, a size of the substrate is close to a predetermined size of the semiconductor package, and the carrier has at least one aperture for containing the substrate therein; providing a heat dissipating structure having a heat dissipating sheet and a plurality of supporting portions extended downwardly from edges of the heat dissipating sheet; mounting the supporting portions of the heat dissipating structure on the carrier with the semiconductor chip being mounted under the heat dissipating sheet; electrically connecting the supporting portions of the heat dissipating structure to the electroconductive layer; forming an encapsulant on the substrate and the carrier to encapsulate the semiconductor chip and the heat dissipating structure; removing a part of the encapsulant above the heat dissipating sheet of the heat dissipating structure by lapping for allowing a part of the heat dissipating sheet to be exposed from the encapsulant; forming a thin metal layer on top surfaces of encapsulant and the part of the heat dissipating sheet exposed from the encapsulant; depositing a metal passivation layer on the thin metal layer via the electroconductive layer of the carrier by a electroplating process; cutting according to the predetermined size of the semiconductor package for obtaining the semiconductor package of the present invention.

The heat dissipating sheet of the heat dissipating structure has a protruding portion on a top center area thereof for allowing a top surface of the protruding portion to be exposed from the encapsulant after lapping the part of the encapsulant. The top surfaces of the encapsulant and the protruding portion are completely covered by the thin metal layer, which is made of copper or nickel, and a metal passivation layer, which is made of nickel, chromium, tin, gold, palladium, or the like, is deposited above the thin metal layer by electroplating for preventing the top surface of the protruding portion from oxidizing, meanwhile, a remaining part of the heat dissipating sheet is still encapsulated inside the encapsulant, for increasing a bonding between the heat dissipating structure and the encapsulant. The heat dissipating sheet further has an extension portion at each of four corners thereof for being connected with the supporting portions, which allows cutting tools cutting through the extension portions only rather than the entire heat dissipating sheet according to the predetermined size of the semiconductor package in a later cutting process, thereby reducing worn out of the cutting tools. A surface, which is opposing to the top surface of the part of the heat dissipating sheet exposed from the encapsulant, of the heat dissipating sheet of the heat dissipating structure is contacted with the semiconductor chip via a heat conductive gel mounted therebetween, thus heat generated during operating of the semiconductor chip is dissipated quickly via the heat dissipating structure.

The present invention further discloses another preferred heat dissipating semiconductor package, which comprises: a substrate; a semiconductor chip mounted on and electrically connected to the substrate; a heat dissipating sheet mounted on the semiconductor chip via a heat conductive gel; an encapsulant formed on the substrate to encapsulate the semiconductor chip with a top surface of the heat dissipating sheet exposed therefrom; a thin metal layer completely covers a top surface of the encapsulant and the top surface of the heat dissipating sheet exposed from the encapsulant; and a metal passivation layer formed on the thin metal layer. The heat dissipating sheet has a protruding portion on a center area thereof, and a top surface of the protruding portion is exposed from the encapsulant. The heat dissipating sheet further has an extension portion at each of four corners thereof, where side surfaces of the extension portions are flush with those of the encapsulant.

In view of the foregoing descriptions, the heat dissipating semiconductor package and the fabrication method therefor according to the present invention mainly has the following steps: positioning a substrate having a chip mounted thereon into an aperture of a carrier, wherein the carrier has an electroconductive layer, such as copper foil, preformed thereon; attaching and electrically connecting a heat dissipating structure having a heat dissipating sheet and supporting portions to the carrier via attaching the supporting portions to the carrier and electrically connecting the supporting portions to the electroconductive layer, whereby after an encapsulation and removing a part of the encapsulant to expose a part of the heat dissipating sheet from the encapsulant, electroplating a metal passivation layer, which is made of nickel, chromium, tin, gold, palladium, or the like, above the part of the heat dissipating sheet exposed from the encapsulant by electrifying the electroconductive layer of the carrier via a electroplating equipment, thereby preventing the part of heat dissipating sheet exposed from the encapsulant from oxidizing. Alternatively, after lapping a part of the encapsulant to expose a part of the heat dissipating sheet from the encapsulant, a thin metal layer, such as a thin copper layer or a thin nickel layer could be formed completely on top surfaces of the encapsulant and the part of the heat dissipating sheet exposed from the encapsulant by an electroless plating, and then a metal passivation layer, which is made of nickel, chromium, tin, gold, palladium, or the like, is further formed on the thin metal layer for preventing the part of heat dissipating sheet exposed from the encapsulant from oxidizing.

Furthermore, the heat dissipating sheet of the heat dissipating structure of the present invention has a protruding portion on a center area thereof, where the top surface of the heat dissipating sheet is exposed from the encapsulant with a remaining part of the heat dissipating sheet remaining encapsulated inside the encapsulant for increasing a bonding between the heat dissipating structure and the encapsulant. The heat dissipating sheet further has an extension portion at each of four corners thereof for allowing cutting tools cutting through the extension portions only rather than the entire heat dissipating sheet in a subsequent cutting process according to the predetermined planar size, thereby reducing worn out of the cutting tools. A surface, which is opposing to the top surface of the part of the heat dissipating sheet that is exposed from the encapsulant, of the heat dissipating sheet of the heat dissipating structure is contacted with the semiconductor chip via a heat conductive gel, thus heat generated during the semiconductor chip operation is more quickly dissipated by the heat dissipating structure.

### BRIEF DESCRIPTION OF DRAWINGS

The present invention can be more fully understood by reading the following detailed description of the preferred embodiments, with reference made to the accompanying drawings, wherein:

FIGS. 1A to 1C (PRIOR ART) are diagrams showing a heat dissipating semiconductor package according to U.S. Pat. Nos. 6,458,626, and 6,444,498;

FIGS. 2A to 2C (PRIOR ART) are diagrams showing a heat dissipating semiconductor package according to Taiwan Patent No. 1255047;

FIGS. 3A and 3B (PRIOR ART) are diagrams of heat dissipating semiconductor package according to U.S. Pat. No. 5,886,408;

FIGS. 4A to 4F are schematic diagrams of a fabrication method for a heat dissipating semiconductor package according to a first embodiment of the present invention;

FIGS. 5A to 5G are schematic diagrams of a fabrication method for a heat dissipating semiconductor package according to a second embodiment of the present invention; and

FIG. 6 is a diagram of a heat dissipating semiconductor package according to a third embodiment of the present invention.

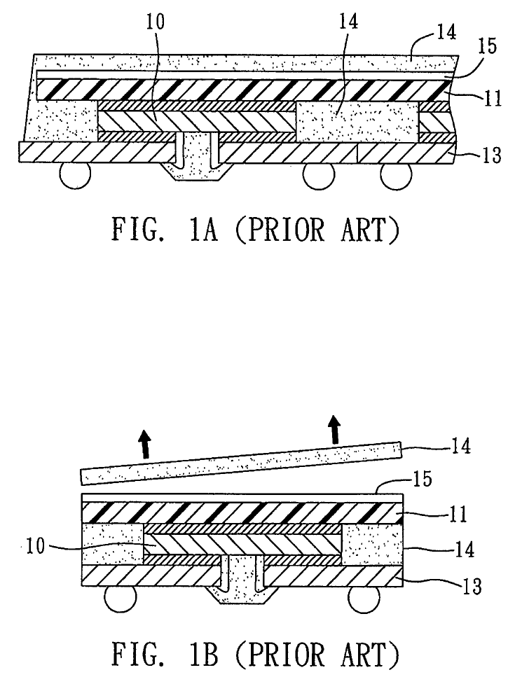

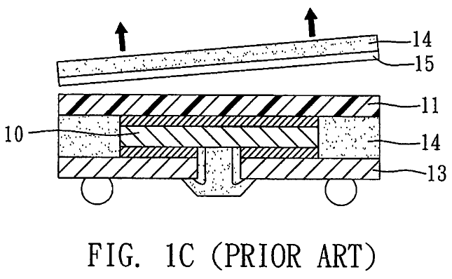

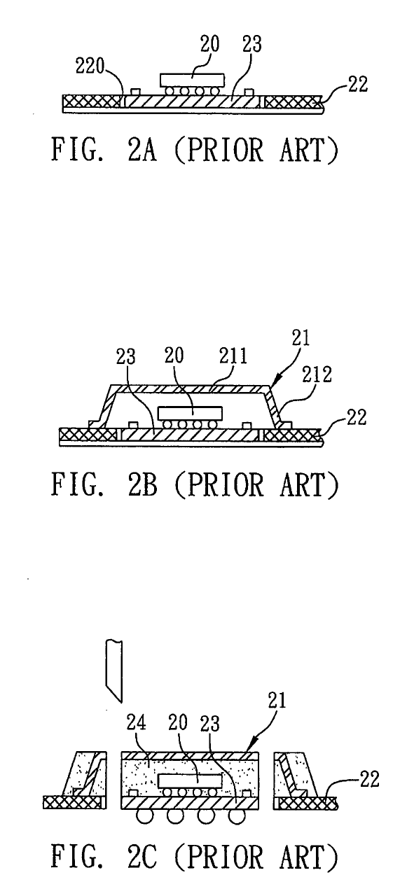

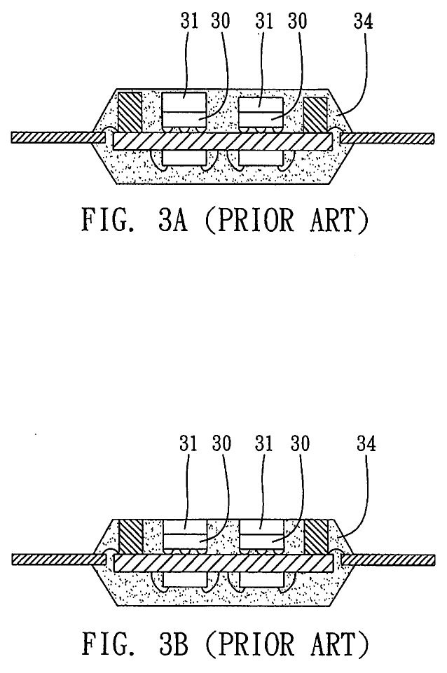

### DETAILED DESCRIPTION OF PREFERRED EMBODIMENTS

The following illustrative embodiments are provided to illustrate the disclosure of the present invention, these and other advantages and effects can be apparently understood by those in the art after reading the disclosure of this specification. The present invention can also be performed or applied by other different embodiments. The details of the specification may be on the basis of different points and applications, and numerous modifications and variations can be devised without departing from the spirit of the present invention.

### First Embodiment

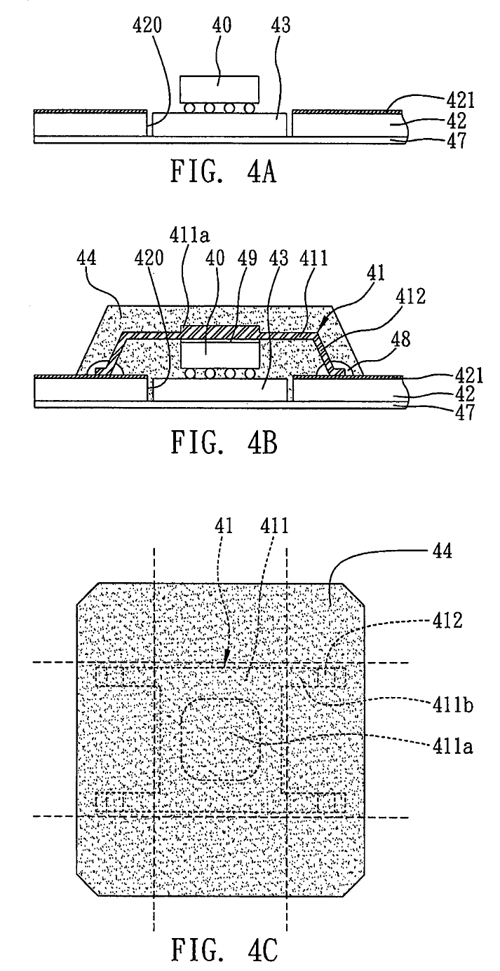

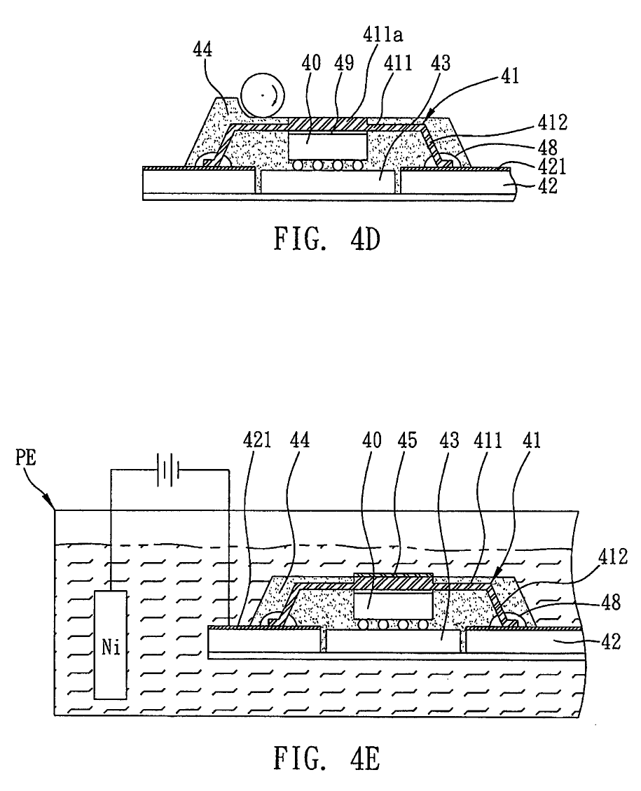

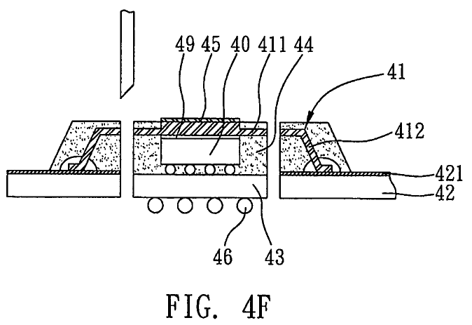

Please refer to FIGS. 4A to 4F, which are diagrams of a fabrication method for a heat dissipating semiconductor package according to the first embodiment of the present invention.

As shown in FIG. 4A, a substrate 43 and a carrier 42 are provided, where a planar size of the substrate 43 is close to a predetermined planar size of a semiconductor package to be formed. At least one semiconductor chip 40 is mounted on and electrically connected to the substrate 43. The semiconductor chip 40 can be electrically connected to the substrate 43 by means of flip chip technique as shown in FIG. 4A or by wire bonding (not shown).

The carrier 42 has an aperture 420 and a electroconductive layer 421, and the planar size of the aperture 420 is larger than that of the substrate 43 for allowing the substrate 43 with the semiconductor chip 40 mounted thereon being disposed in the aperture 420, meanwhile, a tape 47 could be applied on bottom surfaces of the substrate 43 and the carrier 42 to cover gaps between the substrate 43 and the aperture 420 for positioning the substrate 43 and sealing the gap at the same time.

The tape 47 could be made of a high temperature resistant polymer, and the carrier 42 can be made of an organic insulating material, such as FR4, FR5, BT, and etc., with the electroconductive layer 421 (such as a copper foil) on one or both surfaces thereof. The aperture 420 of the carrier 42 can be one or more for containing therein one or more substrate having a chip mounted thereon. Alternatively, the gaps between the substrates 43 and the carrier 42 could be covered or sealed by a plurality of small size tapes, thereby reducing the amount of tape needed. Alternatively, the gaps between the substrates 43 and the carrier 42 could be filled with a gel made of polymer, e.g. solder resist or epoxy (not shown), in order to position the substrate 43 and to seal the gaps.

Please refer to FIGS. 4B and 4C, wherein, FIG. 4C is a top view diagram corresponding to FIG. 4B. A heat dissipating structure 41 made of a material, e.g., copper, is provided, where the heat dissipating structure 41 includes a heat dissipating sheet 411 and a supporting portions 412 extended downwardly from edges of the heat dissipating sheet 411. The supporting portions 412 of the heat dissipating structure 41 is mounted on and electrically connected to the electroconductive layer 421 of the carrier 42. The heat dissipating sheet 411 is attached on the semiconductor chip 40 by a heat conductive gel 49. Therefore, heat generated during an operation of the semiconductor chip can be directly dissipated via the heat dissipating structure 41.

The heat dissipating sheet 411 of the heat dissipating structure 41 has a protruding portion 411a on the center area thereof, and an extension portion 411b extended at each of four corners thereof, where the extension portions 411b are connected with the supporting portions 412. As shown in FIG. 4C, only the extension portions 411b of the heat dissipating structure 41 are at predetermined cutting paths (shown as the dashed lines) of the semiconductor package, for allowing a cutting tool cutting through only the extension portions 411b rather than the entire heat dissipating sheet 411 in the later cutting process according to the predetermined size of the semiconductor package, thereby reducing worn out of the cutting tool.

Next, an encapsulant 44 is formed on the carrier 42 and the substrate 43 to encapsulate the semiconductor chip 40 and the heat dissipating structure 41. A planar size covered by the encapsulant 44 is larger than a planar size surrounded by the supporting portions 412 of the heat dissipating structure 41, and a thickness of the encapsulant 44 is larger than a height of the heat dissipating structure 41, thus the encapsulant 44 can cover the heat dissipating structure 41 completely. Meanwhile, the encapsulant 44 is capable of filling up into the gaps between the substrates 43 and the apertures 420 of the carrier 42.

As shown in FIG. 4D, a part of the encapsulant 44 above a top surface of the heat dissipating sheet 411 of the heat dissipating structure 41 is removed to expose the heat dissipating sheet 411 from the encapsulant 44 by means of, e.g., lapping or the like. In other words, the protruding portion 411a that is on the top surface of the heat dissipating sheet 411 is exposed from the encapsulant 44, meanwhile, a remaining part of the heat dissipating sheet 411 is remained encapsulated inside the encapsulant 44 in order to increase the bonding between the heat dissipating structure 41 and the encapsulant 44.

As shown in FIG. 4E, the carrier 42, which has proceed with the encapsulation process and also has a part of the heat dissipating structure 41 being exposed from the encapsulant 44, i.e. the top surface of the heat dissipating sheet 411, is positioned into a plating equipment for an electroplating process, thus depositing and forming a metal passivation layer 45 of, e.g., nickel (Ni), chromium (Cr), tin (Sn), gold (Au), palladium (Pd), or others, on the top surface of the heat dissipating structure 41 by means of electroplating via the configuration of the electroconductive layer 421 and the heat dissipating structure 41 electrically connected thereto. The metal passivation layer 45 has a thickness of about 1 to 3 μm for protecting the part of the heat dissipating structure 41 exposed from the encapsulant 44.

As shown in FIG. 4F, the tape 47 is removed, and then a plurality of solder balls 46 are mounted on a surface of the substrate 43 that has no semiconductor chip mounted thereon. Cutting the semiconductor package along outlines of the predetermined size, namely, about the planar size of the substrate 43, thus the semiconductor package of the present invention is completely produced.

By means of the aforementioned fabrication method, a semiconductor package according to an embodiment of the present invention is disclosed, which comprises: the substrate 43; a semiconductor chip 40 mounted on and electrically connected to the substrate 43; a heat dissipating sheet 411 attached onto the semiconductor chip 40 via a heat conductive gel 49; an encapsulant 44 formed on the substrate 43 to encapsulate the semiconductor chip 40 with a top surface of the heat dissipating sheet 411 exposed therefrom; and a metal passivation layer 45 formed on the top surface of the encapsulant 44 by electroplating.

The heat dissipating sheet 411 has a protruding portion 411a on a top center area thereof for allowing a top surface of the protruding portion 411a to be exposed from the encapsulant 44 after lapping the encapsulant 44, whereby the metal passivation layer 45 could be formed on the top surface of the protruding portion 411a, which is exposed from the encapsulant 44, by electroplating to prevent from the top surface of the protruding portion 411a oxidizing. Furthermore, the heat dissipating sheet 411 comprises an extension portion 411a at each of the four corners thereof. Since the extension portions 411b are on predetermined cutting paths of the semiconductor package, side surfaces of the extension portions 411b are flushed with that of the encapsulant 44.

### Second Embodiment

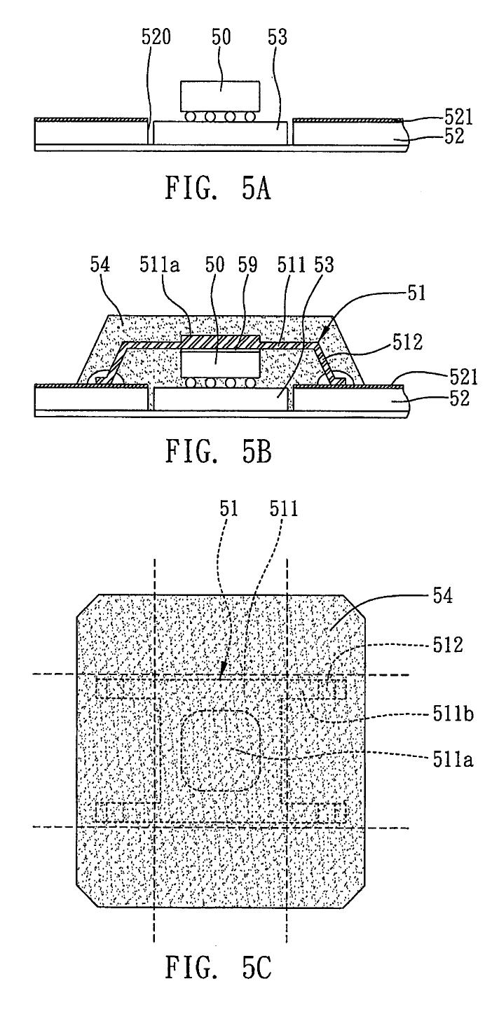

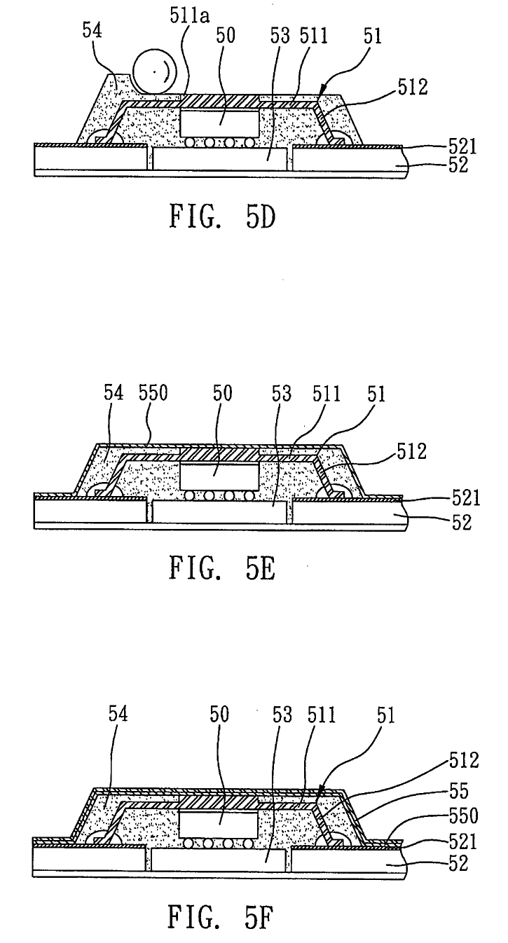

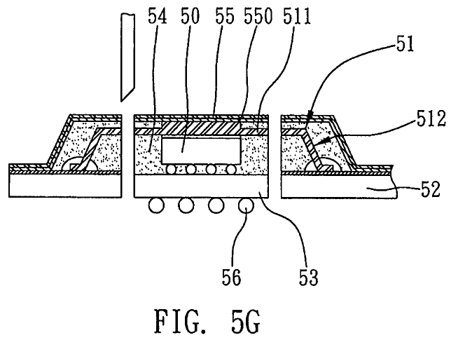

Please refer to FIGS. 5A to 5Q which are diagrams of a fabrication method for a heat dissipating semiconductor package according to the second embodiment of the present invention.

As shown in FIG. 5A, a substrate 53 and a carrier 52 are provided, where the size of the substrate 53 is close to a predetermined size of the semiconductor package, and a semiconductor chip 50 is mounted on the substrate 53. The carrier 52 has an aperture 520 and also has an electroconductive layer 521 on the surface thereof, where a size of the aperture 520 is larger than a size of the substrate 53 for containing the substrate 53 therein.

As shown in FIGS. 5B and 5C, wherein, FIG. 5C is a top view diagram corresponding to FIG. 5B. A heat dissipating structure 51 comprising a heat dissipating sheet 511 and a plurality of supporting portions 512 that are extended downwardly from edges of the heat dissipating sheet 511 is provided, where the supporting portions 512 of the heat dissipating structure 51 is mounted on and electrically connect to the electroconductive layer 521 of the carrier 52, while the semiconductor chip 50 is connected to the heat dissipating sheet 511 via a heat conductive gel 59.

The heat dissipating sheet 511 of the heat dissipating structure 51 has a protruding portion 511a on a top surface thereof, and has an extension portion 511b for being connected with the supporting portions 512 at each of four corners thereof. As shown in FIG. 5C, only the extension portions 511b of the heat dissipating structure 51 are on predetermined cutting paths (the dashed lines) of the semiconductor package, thus in the later cutting process, cutting tools cutting through the extension portions 511b only rather than the entire heat dissipating sheet according to the predetermined size of the semiconductor package, thereby reducing worn out of cutting tools.

Then, an encapsulant 54 is formed on the carrier 52 and the substrate 53 to encapsulate the semiconductor chip 50 and the heat dissipating structure 51.

As shown in FIG. 5D, the encapsulant 54 above the top surface of the heat dissipating sheet 511 of the heat dissipating structure 51 is removed by means of lapping or the like in order to expose the heat dissipating sheet 511 from the encapsulant 54. In other words, the protruding portion 511a that is on the top surface of the heat dissipating sheet 511 is exposed from the encapsulant 54.

As shown in FIG. 5E, a thin metal layer 550 is formed to completely cover the top surface of the encapsulant 54 and the top surface of heat dissipating sheet 511 exposed from the encapsulant 54. The thin metal layer 550 is either a thin copper layer or a thin nickel layer with a thickness of about 0.1 to 0.5 μm and can be formed by means of electroless plating.

As shown in FIG. 5F, a metal passivation layer 55 of, e.g., nickel, chromium, tin, gold, palladium, or others, is deposited and formed on a top surface of the thin meal layer 550 via the configuration of the electroconductive layer 521 of the carrier 52 and the heat dissipating structure 51 by using the aforementioned plating equipment and process, where the metal passivation layer 45 has a thickness of about 1 to 3 μm.

As shown in FIG. 5G, a cutting process is performed to cut along the outlines of the predetermined size of the semiconductor package and then a plurality of solder balls 56 are configured to complete the heat dissipating semiconductor package.

By means of the foregoing fabrication method, the heat dissipating semiconductor package of the present invention comprises: a substrate 53; a semiconductor chip 50, mounted on and electrically connected to the substrate 53; a heat dissipating sheet mounted on the semiconductor chip 50 by a heat conductive gel 59; an encapsulant 54, formed on the substrate 53 to encapsulate the semiconductor chip 50 with a top surface of the heat dissipating sheet 511 exposed therefrom; a thin metal layer 550 completely covering a top surface of the encapsulant 54 and the top surface of the heat dissipating sheet 511 exposed from the encapsulant 54; and a metal passivation layer 55 deposited on the top surface of the thin metal layer 550 by means of electroplating.

### Third Embodiment

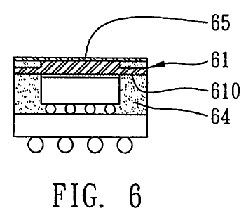

Please refer to FIG. 6, which is a diagram of a heat dissipating semiconductor package according to the third embodiment of the present invention.

As shown in the FIG. 6, the heat dissipating semiconductor package of the present embodiment is similar to the foregoing embodiment, and the present embodiment is different from the foregoing embodiment in that a heat dissipating structure 61 of the present embodiment is further processed with a roughening treatment that can be made by a acidity or alkaline chemical to form a rough surface 610, where the rough surface 610 provides a better bonding between the heat dissipating structure 61 and an encapsulant 64, and is also good for the later coating process for forming a metal passivation layer 65 that covers a part of the heat dissipating structure 61 exposed from the encapsulant 64 after the process of removing a part of the encapsulant 64 by means of electroplating.

In summary, the heat dissipating semiconductor package and the fabrication method therefore according to the present invention mainly has the following steps: containing a substrate having a chip mounted thereon in an aperture of a carrier, wherein the carrier has an electroconductive layer, e.g., a copper foil, on a surface thereof, allowing a heat dissipating structure having supporting portions being mounted on and electrically connected to the electroconductive layer of the carrier via the supporting portions thereof, whereby, after an encapsulation process and removing a part of the encapsulant above the heat dissipating sheet by lapping to expose the heat dissipating structure from the encapsulant, allowing electrifying the electroconductive layer of the carrier with a plating equipment for depositing and forming a metal passivation layer of, e.g., nickel, chromium, tin, gold, palladium, or others, on a surface of the part of the heat dissipating structure exposed from the encapsulant for preventing the exposed heat dissipating structure from oxidizing. Alternatively, after lapping a part of the encapsulant to expose a part of the heat dissipating sheet from the encapsulant, a thin metal layer, such as a thin copper layer or a thin nickel layer could be formed completely on a top surface of the encapsulant and a top surface of the part of the heat dissipating sheet exposed from the encapsulant by an electroless plating, and then a metal passivation layer, which is made of nickel, chromium, tin, gold, palladium, or the like, is further formed on the thin metal layer preventing the part of heat dissipating sheet exposed form the encapsulant from oxidizing.

Furthermore, the heat dissipating sheet of the heat dissipating structure of the present invention has a protruding portion on a center area thereof, where a top surface of the protruding portion is exposed from the encapsulant with a remaining part of the heat dissipating sheet remaining encapsulated inside the encapsulant for increasing bonding between the heat dissipating structure and the encapsulant. The heat dissipating sheet further has an extension portion at each of four corners thereof for allowing a cutting tool cutting through the extension portions only rather than the entire heat dissipating sheet in a subsequent cutting process according to the predetermined planar size, thereby reducing worn out of the cutting tool. A surface, which is opposing to a top surface of the part of the heat dissipating sheet exposed from the encapsulant, of the heat dissipating sheet of the heat dissipating structure is contacted with the semiconductor chip via a heat conductive gel, thus the heat generated during the semiconductor chip operation is dissipated by the heat dissipating structure.

The foregoing descriptions of the detailed embodiments are only illustrated to disclose the features and functions of the present invention and not restrictive of the scope of the present invention. It should be understood to those in the art that all modifications and variations according to the spirit and principle in the disclosure of the present invention should fall within the scope of the appended claims.

What is claimed is:

1. A fabrication method for a heat dissipating semiconductor package, comprising the step of:
providing a substrate having a semiconductor chip mounted thereon and a carrier having an electroconductive layer on a surface thereof and at least one aperture for containing the substrate therein, wherein, a size of the substrate is close to a predetermined size of the semiconductor package;
providing a heat dissipating structure having a heat dissipating sheet and a plurality of supporting portions extended downwardly from edges of the heat dissipating sheet with the supporting portions of the heat dissipating structure being mounted on and electrically connected to the electroconductive layer;
forming an encapsulant on the substrate and the carrier to encapsulate the semiconductor chip and the heat dissipating structure;
removing a part of the encapsulant above the heat dissipating sheet of the heat dissipating structure with a part of the heat dissipating sheet exposed from the encapsulant;
electroplating a metal passivation layer on the part of the heat dissipating sheet exposed from the encapsulant via the electroconductive layer of the carrier; and
cutting according to the predetermined size of the semiconductor package.

2. The fabrication method of claim 1, wherein, the carrier has a copper foil on at least one surface thereof, and is made of an organic insulating material being one selected from a group consisting of FR4, FR5, BT, and a combination thereof.

3. The fabrication method of claim 1, wherein the heat dissipating sheet of the heat dissipating structure is attached to a top surface of the semiconductor chip via a heat conductive gel.

4. The fabrication method of claim 1, wherein the supporting portions of the heat dissipating structure are mounted on and electrically connected to the electroconductive layer of the carrier via an electroconductive gel.

5. The fabrication method of claim 1, wherein the heat dissipating sheet of the heat dissipating structure has a protruding portion protruded from a center area thereof, a top surface of the protruding portion is exposed from the encapsulant for serving as the part of the heat dissipating sheet exposed from the encapsulant, and the heat dissipating sheet has an extension portion at each of four corners thereof with only the extension portions of the heat dissipating structure being positioned at predetermined cutting paths of the semiconductor package, where the extension portions are connected with the supporting sections.

6. The fabrication method of claim 5, wherein the part of the encapsulant above the heat dissipating sheet is removed by a lapping, thus the top surface of the protruding portion is exposed from the encapsulant, meanwhile, a remaining part of the heat dissipating sheet is still encapsulated inside the encapsulant.

7. The fabrication method of claim 5, wherein, side surfaces of the extension portions are flush with that of the encapsulant.

8. The fabrication method of claim 1, wherein, the metal passivation layer has a thickness of about 1 to 3 μm, and is made of one selected from a group consisting of nickel, chromium, tin, gold, and palladium.

9. The fabrication method of claim 1, further comprising a roughening treatment on a surface of the heat dissipating structure to form a rough surface thereof, thus providing a better bonding between the heat dissipating structure and the encapsulant.

10. A fabrication method for a heat dissipating semiconductor package, comprising steps of:
providing a substrate having a semiconductor chip mounted thereon, and a carrier having at least one aperture for containing the substrate therein and an electroconductive layer on a surface thereof, wherein, a size of the substrate is close to a predetermined size of the semiconductor package;
providing a heat dissipating structure having a heat dissipating sheet and a plurality of supporting portions extended downwardly from edges of the heat dissipating sheet with the supporting portions of the heat dissipating structure being mounted on and electrically connected to the electroconductive layer;
forming an encapsulant on the substrate and the carrier to encapsulate the semiconductor chip and the heat dissipating structure;
removing a part of the encapsulant above the heat dissipating sheet of the heat dissipating structure with a part of the heat dissipating sheet exposed from the encapsulant;
forming a thin metal layer on the part of the heat dissipating sheet exposed from the encapsulant,
electroplating a metal passivation layer on the thin metal layer via the electroconductive layer of the carrier; and
cutting according to the predetermined size of the semiconductor package.

11. The fabrication method of claim 10, wherein, the carrier has a copper foil on at least one surface thereof, and is made of an organic insulating material being one selected from a group consisting of FR4, FR5, BT, and a combination thereof.

12. The fabrication method of claim 10, wherein the heat dissipating sheet of the heat dissipating structure is attached to a top surface of the semiconductor chip via a heat conductive gel.

13. The fabrication method of claim 10, wherein the supporting portions of the heat dissipating structure are mounted on and electrically connected to the electroconductive layer of the carrier via an electroconductive gel.

14. The fabrication method of claim 10, wherein, the heat dissipating sheet of the heat dissipating structure has a protruding portion protruded from a center area thereof, a top surface of the protruding portion is exposed from the encapsulant for serving as the part of the heat dissipating sheet exposed from the encapsulant, and the heat dissipating sheet has an extension portion at each of four corners thereof with only the extension portions of the heat dissipating structure being positioned at predetermined cutting paths of the semiconductor package, where the extension portions are connected with the supporting sections.

15. The fabrication method of claim 14, wherein the part of the encapsulant above the heat dissipating sheet is removed by lapping, thus the top surface of the protruding portion is exposed from the encapsulant, meanwhile, a remaining part of the heat dissipating sheet is still encapsulated inside the encapsulant.

16. The fabrication method of claim 10, wherein the metal passivation layer has a thickness of about 1 to 3 μm, and is made of one selected from a group consisting of nickel, chromium, tin, gold, and palladium.

17. The fabrication method of heat dissipating semiconductor package of claim 10, wherein the thin metal layer is one of a thin copper layer and a thin nickel layer with a thickness of about 0.1 to 0.5 μm and is formed by an electroless plating.

18. The fabrication method of claim 10, further comprising a roughening treatment on a surface of the heat dissipating structure to form a rough surface thereof, thus providing a better bonding between the heat dissipating structure and the encapsulant.

19. A heat dissipating semiconductor package, comprising:
a substrate;
a semiconductor chip mounted on and electrically connected to the substrate;
a heat dissipating sheet mounted on the semiconductor chip by a heat conductive gel;
an encapsulant formed on the substrate to encapsulate the semiconductor chip with a top surface of the heat dissipating sheet exposed therefrom; and
a metal passivation layer formed on the top surface of the heat dissipating sheet exposed from the encapsulant.

20. The heat dissipating semiconductor package of claim 19, wherein the heat dissipating sheet has a protruding portion on a center area thereof for allowing the top surface of the heat dissipating sheet to be exposed from the encapsulant with a remaining part of the heat dissipating sheet being encapsulated inside the encapsulant.

21. The heat dissipating semiconductor package of claim 19, wherein the heat dissipating sheet further has an extension portion at each of four corners thereof, and side surfaces of the extension portions are flush with that of the encapsulant.

22. The heat dissipating semiconductor package of claim 19, wherein the metal passivation layer has a thickness of about 1 to 3 μm, and is made of one selected from a group consisting of nickel, chromium, tin, gold, and palladium.

23. The heat dissipating semiconductor package of claim 19, wherein the heat dissipating sheet has a rough surface formed by a roughening treatment for providing a better bonding between the heat dissipating sheet and the encapsulant.

24. The heat dissipating semiconductor package of claim 19 further comprising:
a thin metal layer completely covering a top surface of the encapsulant and the top surface of the heat dissipating sheet exposed from the encapsulant, wherein the metal passivation layer is formed on the thin metal layer.

25. The heat dissipating semiconductor package of claim 24, wherein the thin metal layer is one of a thin copper layer and a thin nickel layer with a thickness of about 0.1 to 0.5 μm and is formed by an electroless plating.
